(19) United States
(12) Patent Application Publication
(10) Pub. No.: US 2025/0260253 A1
(43) Pub. Date: Aug. 14, 2025

(54) Average Input Current Built-In Self-Test and Calibration

(71) Applicant: Apple Inc., Cupertino, CA (US)

(72) Inventors: Nicolò Nizza, Marsala (IT); Corrado Roberto Giuseppe Marino, Pisa (IT)

(21) Appl. No.: 18/437,512

(22) Filed: Feb. 9, 2024

(51) Int. Cl. H02J 7/00; G01R 19/10

(52) U.S. Cl. CPC H02J 7/00714; G01R 19/10

(57) ABSTRACT

An apparatus for performing an average input current self-test and calibration is disclosed. The apparatus includes an input circuit configured to receive power from an external source and an error amplifier configured to generate an error signal based on a difference between a current limit value and the value of an input current generated by the input circuit. A calibration circuit is configured to perform, using the error signal, a calibration to determine the current limit value. A limit circuit configured to regulate the input current received by the input circuit based on the current limit value.

### BACKGROUND

### Technical Field

This disclosure is directed to electronic circuits, and more particularly, to self-test circuit for testing circuit parameters such as current.

### Description of the Related Art

The use of portable electronic devices has become widespread in recent decades. Such devices include smartphones, tablet computers, laptop computers, and so on. Many such portable electronic devices utilize a rechargeable battery to provide power to the circuits therein. Devices having a rechargeable battery also include a charging circuit for coupling an external power source to the device to charge the battery. Such devices include regulation circuits for regulating the input current. The testing of these devices may be conducted on automated test equipment using open loop testing.

### SUMMARY

An apparatus for performing an average input current self-test and calibration is disclosed. In one embodiment, the apparatus includes an input circuit configured to receive power from an external source and an error amplifier configured to generate an error signal based on a difference between a current limit value and the value of an input current generated by the input circuit. A calibration circuit is configured to perform, using the error signal, a calibration to determine the current limit value. A limit circuit configured to regulate the input current received by the input circuit based on the current limit value.

In one embodiment, the circuitry of the present disclosure may be used to calibrate an input current provided by a charging circuit for a portable device having a rechargeable battery. The calibration circuit includes comparators configured to cause, during the calibration, a counter to increment or decrement, based on the level of the error signal. After a specified time period, the average count value is determined based on the count values obtained during the calibration process. The current limit is then set based on the average count value.

### BRIEF DESCRIPTION OF THE DRAWINGS

The following detailed description makes reference to the accompanying drawings, which are now briefly described.

FIG. 1 is a block diagram of one embodiment of a circuit used to calibrate and regulate an input current.

FIG. 2A is a schematic diagram of one embodiment of a circuit used to calibrate and regulate an input current.

FIG. 2B is a schematic diagram of another embodiment of a circuit used to calibrate and regulate an input current

FIG. 3A is a timing diagram illustrating a calibration procedure carried out by one embodiment of a circuit for calibrating an input current.

FIG. 3B is a timing diagram illustrating a calibration procedure carried out by another embodiment of a circuit for calibrating an input current.

FIG. 4 is a block diagram of one embodiment of a portable device coupled to an embodiment of an external power source.

FIG. 5 is a flow diagram of one embodiment of a method for carrying out a calibration and regulation of an input current.

FIG. 6 is a flow diagram of another embodiment of a method for carrying out a calibration and regulation of an input current.

FIG. 7 is a block diagram of one embodiment of a device that may utilize the filter arrangement of the present disclosure.

FIG. 8 is a diagram illustrating different systems that may utilize the filter arrangement of the disclosure.

FIG. 9 is a diagram of one embodiment of a non-transitory computer readable medium that stores circuit design information including circuits in accordance with the disclosure.

### DETAILED DESCRIPTION OF EMBODIMENTS

Portable electronic devices, such as smartphones, tablets, and so on, have become ubiquitous in recent years. Such devices may operate using the power of a rechargeable battery when not coupled to an external power source. Accordingly, these types of portable devices include charging circuitry for charging the battery when external power is available.

In charging a battery of a portable device, power must be applied thereto at a specified voltage and input current. Limiting the current is important so as to not damage the battery and/or the external power source. Accordingly, before such portable devices are shipped for sale, testing is conducted of the charging circuitry to calibrate and set an appropriate current limit. Such testing may be conducted in using automated test equipment (ATE). In conducting the test, the control loop for regulating the input current may be opened, with the ATE using a regulation circuit to set current limit values. However, this method of testing and calibration is not accurate since the regulation circuit load condition during the test/calibration is different from that in an operational environment.

The present disclosure makes use of the insight that the addition of a small amount of built-in self-test (BIST) and calibration circuitry could result in a closed-loop test and calibration to effectively calibrate the current limit. Accordingly, the present disclosure is directed to a BIST/calibration circuit that tests the value of the input current and calibrates the same for mission mode operations. A calibration circuit is added and allows for a closed-loop determination of the input current and calibration of current limits based thereon. The testing/calibration may be conducted over a specified period, with the calibration circuit determining a current limit value upon completion of the period.

In one embodiment, an error amplifier is used to cause a counter to increment or decrement during the specified period. The count value is used to control a limit circuit, which in turn controls a voltage provided to one input terminal of an error amplifier, with the other input terminal receiving a voltage corresponding to the input current. At the end of the specified period, an average count value is determined and used to set the current limit for mission mode (normal) operations. This allows for testing the input current and determining a current limit value under conditions that are closer to those encountered during mission mode operation. Furthermore, the mechanism disclosed herein allows for the test/calibration to be carried out without the use of complex regulation circuits in conjunction with ATE.

Various embodiments are now discussed in further detail. The discussion begins with embodiments of a calibration circuit used to calibrate an input current limit for a charging circuit used to charge a battery. Timing diagrams illustrating operation of different embodiments are also discussed. An example of a portable device having a battery and a charging circuit is described, followed by methods for carrying out testing and calibration of an input current limit, followed by descriptions of an example device and an example system in which the arrangement may be implemented, followed by one for a computer readable medium that stores instructions usable to manufacture such devices and systems.

Charging Circuit with BIST/Calibration Circuitry:

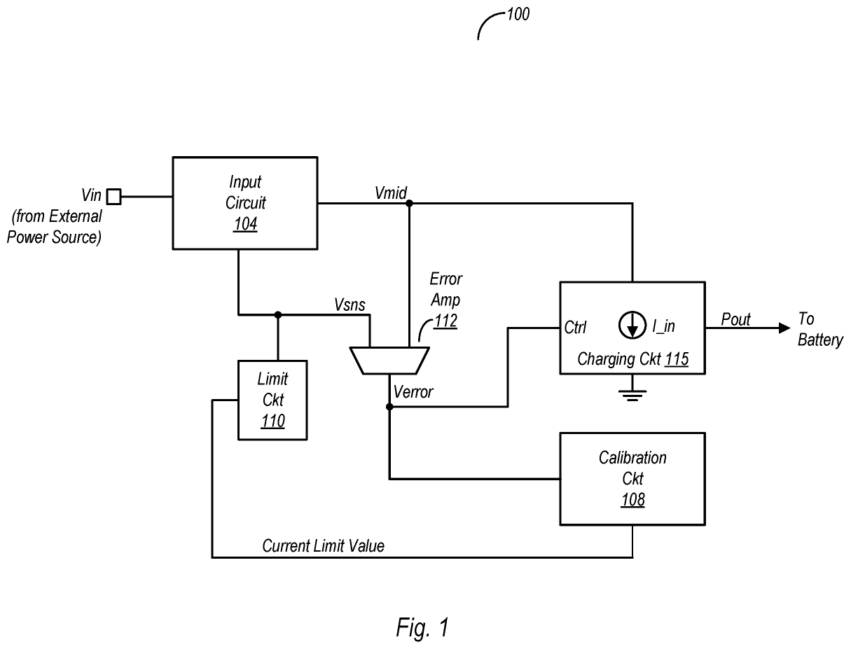

FIG. 1 is a block diagram of one embodiment of a circuit used to calibrate and regulate an input current. In the embodiment shown, circuit 100 includes an input circuit 104, a limit circuit 110, a charging circuit 115, an error amplifier 112, and a calibration circuit 108. Input circuit 104 in the embodiment shown is coupled to receive an input voltage, Vin, from an external power source. Charging circuit 115 in the embodiment shown is configured to provide power, Pout, based on an input current value of I_in, to a rechargeable battery. Circuit 100 may be implemented in a portable device having a rechargeable battery. Such devices may include, but are not limited to, smartphones, laptop computers, tablet computers, and so on.

Input circuit 104 in the embodiment shown is coupled to receive a voltage from an external power source. The input voltage may be received through any suitable connection type. The external source may be an external charger, a power adapter for a wall outlet, or any other source that may provide power. Input circuit 104 may generate or pass a voltage, Vmid, to a charging circuit 115. The voltage Vmid may also be provided to an input of an error amplifier 112. Input circuit 104 in the embodiment shown also generates a second voltage, Vsns, which is provided to a second input of error amplifier 112. This voltage may be modified by limit circuit 110, as will be explained in further detail below.

Error amplifier 112 in the embodiment shown is configured to generate an error signal, Verror, based on the difference in voltage between Vmid and Vsns. The error signal is provided to charging circuit 115, via a control input, Ctrl. The error signal is also provided to a calibration circuit 108, which may carry out self-test and calibration of a limit current value.

Charging circuit 115 in the embodiment shown is configured to provide power, Pout, to a rechargeable battery, at an input current value of I_in. The input current, and thus the charging current used to charge the battery, may be controlled by charging circuit 115 using the error signal, Verror, received from error amplifier 112. Accordingly, variations in the voltage of the error signal may cause corresponding variations in the current received by the battery from charging circuit.

Limit circuit 110 in the embodiment shown is configured to modify the voltage Vsns based on a current limit value. In one embodiment, the current limit value may be digitally stored in a register within limit circuit 110, with this digital value being converted into an analog signal that modifies the voltage Vsns. This in turn affects the level of the error signal generated by error amplifier 112 that is provided to the control input of charging circuit 112. Accordingly, limit circuit 110, using the current limit value, contributes to the regulation of the current provided to the battery.

The current limit value stored in limit circuit 110 may be set by calibration circuit 108. Using the error signal, calibration circuit 108 may carry out a calibration routine to determine the current limit value. This calibration routine may be carried out in lieu of one that utilizes ATE and requires performing the calibration in an open-loop fashion. Accordingly, the current limit value may be set at a more optimal value using conditions that more closely correspond to those that the portable device encounters during mission mode operations.

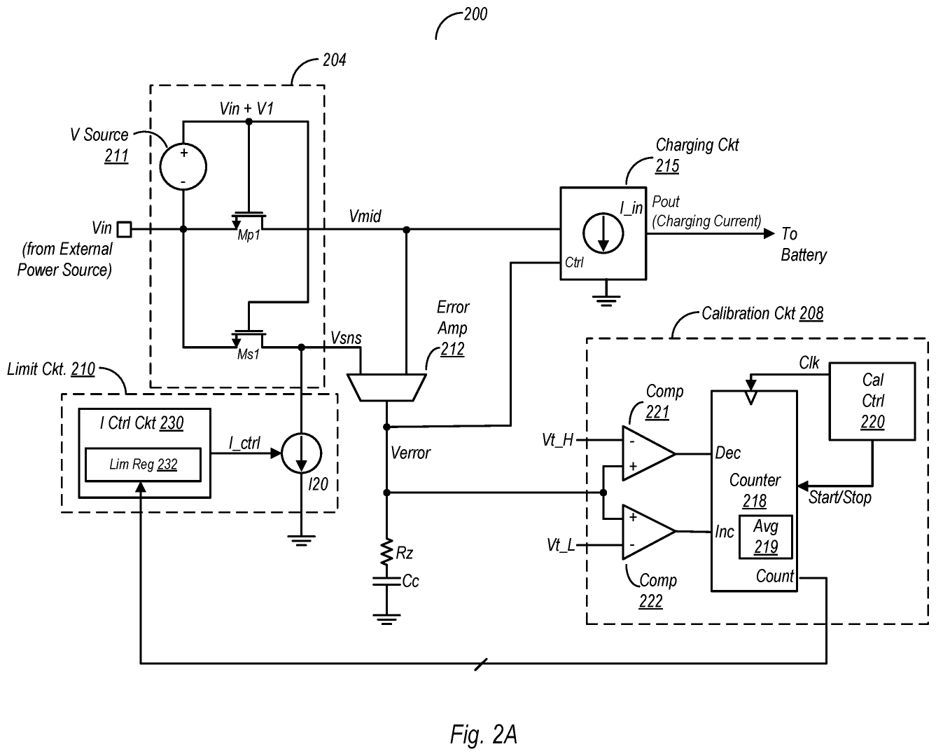

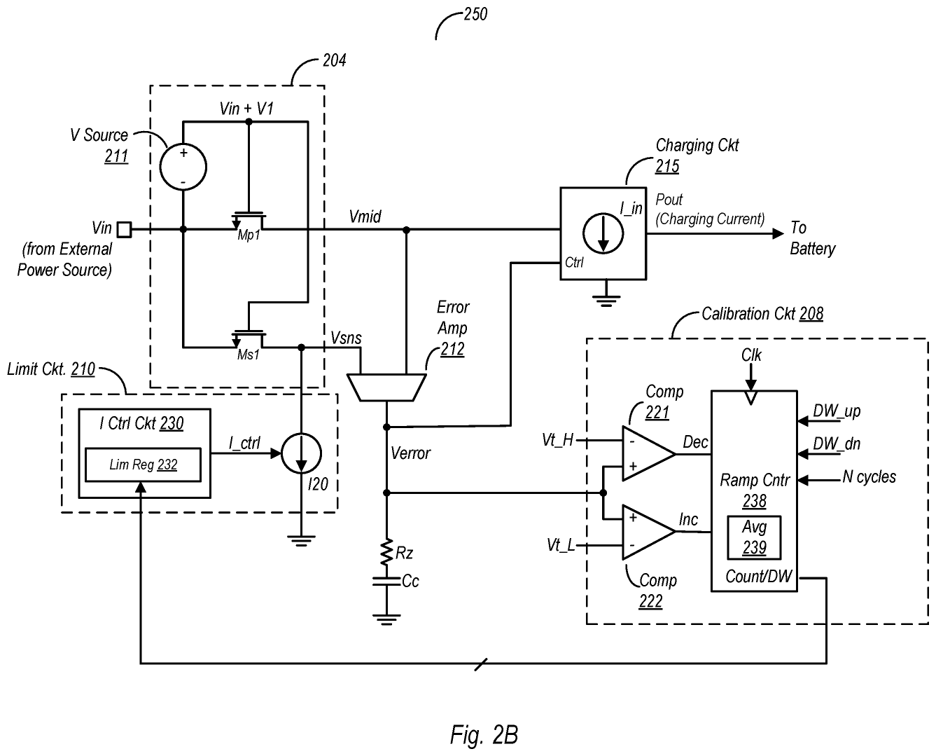

FIG. 2A is a schematic diagram of one embodiment of a circuit used to calibrate and regulate an input current. In the embodiment shown, circuit 200 includes an input circuit 204, a limit circuit 210, a charging circuit 215, a calibration circuit 208, and an error amplifier 212.

Input circuit 204 in the embodiment shown includes a pair of pass devices, Mp1 and Ms1, implemented here as NMOS transistor. The source terminals of both Mp1 and Ms1 are coupled to an input pin through which an input voltage, Vin, may be received from an external source. Pass device Mp1 in the embodiment shown, using Vin, provides the voltage Vmid (via its drain terminal) to charging circuit 215 as well as to one of the inputs of error amplifier 212. Pass device Ms1 provides at least a portion of the voltage Vsns (via its drain terminal), to a second input of the error amplifier. As will be discussed below, the voltage Vsns may be modified by limit circuit 210.

A voltage source 211 is also coupled to the input pint, and is configured to generate a voltage Vin+V1, which is used to drive the gate terminals of Mp1 and Mn1 when an external source is coupled to the input pin. Voltage source 211 may be implemented using a charge pump or other circuitry suitable for generating a voltage greater than Vin to provide a sufficient voltage to enable activation of Mp1 and Ms1 when an external power source is providing Vin. These devices may otherwise remain inactive when no external power source is coupled thereto, and thus the battery is not undergoing charging.

Charging circuit 215 in the embodiment shown may function similar to that discussed above with reference to FIG. 1. More particularly, charging circuit 215 in the embodiment shown is coupled to receive the voltage Vmid as well as the error signal Verror (received in the Ctrl input). Using these two signals, charging circuit 215 generates power, Pout, that is provided to a battery during charging, based on input current value of I_in. This current value is regulated based on the current limit value set by limit circuit 210, and determines the charging current provided to the battery.

Error amplifier 212 in the embodiment shown is configured to generate the error signal Verror, in conjunction with resistor Rz and capacitor Cc. Capacitor Cc in this embodiment is an integration capacitor, thereby integrating the error signal Verror over time.

Calibration circuit 208 in the embodiment shown includes a pair of comparators 221 and 222, a counter 218 (which includes an averaging circuit 219), and a calibration control circuit 220. Each of the comparators 221 and 222 in the embodiment shown is coupled to receive the error signal Verror on their respective non-inverting inputs. The inverting input of comparator 221 is configured to receive a first threshold voltage Vt_H, which may correspond to a peak voltage. The inverting input of comparator 222 is configured to receive a second threshold voltage, Vt_L, which may correspond to a valley voltage. These two comparators may perform continuous comparisons of the error signal voltage level to their respectively received thresholds.

If the error signal voltage meets or exceeds the voltage Vt_H, comparator 221 may assert an output signal received by the Dec input of counter 218. This may cause counter 218 to begin decrementing the count value. If the error signal voltage is less than or equal to the threshold voltage Vt_L, comparator 222 may assert a signal received on the Inc input of counter 218, causing it to increment the count value.

Limit circuit 210 in the embodiment shown includes a current source 120, and a current control circuit 230, which in turn includes a limit register 232. In the embodiment shown, limit register 232 stores a current limit value that corresponds to a count value received from counter 218. Current control circuit 230 may include circuitry therein which converts this current limit value into the control signal I_ctrl. Using this control signal, the current generated by current source 120 may be varied, which in turn causes variations to the voltage Vsns. As a result, the level of the error signal Verror also varies, thereby causing a change to the input current I_in generated by charging circuit 215.

During a calibration, counter 218 may increment and decrement the count value based on the comparisons of the error signal to the respective threshold voltages received by comparators 221 and 222. During this time, the varying count is provided to the limit register 232 in limit circuit 210, thereby varying the current limit value. In this embodiment, the calibration is initiated with the assertion of a Start signal, and is synchronized with a clock signal, Clk. Each update to the count value may be conveyed to the limit register 232, thereby causing variations in the current drawn by current source 120, with resulting variations to the voltage Vsns and the level of the error signal. The calibration may be conducted over a specified number of clock cycles. It is noted that during this calibration, Verror is not provided to charging circuit 215. For example, a switch may be present in the path between the output of error amplifier 212 and the Ctrl input of charging circuit 215, with this switch being open during the calibration procedure. As such, the current drawn by charging circuit 215 (and thus Vmid) may remain at a fixed value as the calibration is carried out.

During the calibration, the count values generated by counter 218 may be accumulated in, e.g., a temporary storage circuit within averaging circuit 219. After the calibration control circuit 220 asserts the Stop signal, averaging circuit may sum the count values and determine the average by dividing this sum by the number of count values generated during the calibration. This average value is then provided to the limit register 232 of limit circuit 210, and thus becomes the current limit value. During charging operations carried out subsequent to the calibration, the input current may thus be regulated using the current limit value. More particularly, since the current limit value affects the voltage Vsns and thus the error signal voltage Verror, charging circuit may adjust the input current using the latter signal as received at the Ctrl input. In some embodiments, charging circuit 215 may operate to maintain the input current within a tolerance range (e.g., ±5%) of the current limit value as indicated by the count value stored in limit register 232.

FIG. 2B is a schematic diagram of another embodiment of a circuit used to calibrate and regulate an input current. In the embodiment shown, circuit 250 includes elements similar to those of circuit 200 in FIG. 2A. However, this embodiment utilizes fixed digital values and counts the duration of the positive and negative ramps of the error voltage using ramp counter 238. As with the embodiment of FIG. 2A, Vmid, and thus the current drawn by charging circuit 215 may remain at fixed values by preventing Verror from being provided to the Ctrl input thereof.

In the embodiment shown, ramp counter 238 is configured to receive values of DW_up and DW_dn. While ramp counter 238 may count and store values internally, it may nevertheless output different values, and does so in this embodiment by providing a fixed value DW_up from the Count/DW output during incrementing operations and providing a fixed value DW_dn from the Count/DW output during incrementing operations.

Ramp counter 238 may begin providing the DW_up count value to limit circuit 210 in response to the error voltage reaching the low threshold, Vt_L, as indicated by comparator 222. When DW_up is provided to limit circuit 210, I_ctrl, and thus Vsns, are adjusted accordingly. Based on the difference between Vsns and Vmid, the error voltage Verror begins ramping up. During this ramp-up, ramp counter begins counting the clock cycles, and thus the time elapsed from the beginning of incrementing. When the error voltage Verror reaches Vt_H, comparator 221 asserts the Dec signal. In response to assertion of the Dec signal, the DW_dn value is provided from the Count/DW output, while the ramp counter again begins counting clock cycles. Additionally, the count value indicative of the duration of the up-ramp is also stored in, e.g., a register or other storage structure within ramp counter 238.

In response to receiving the DW_dn value, limit circuit 210 again adjusts the current I_ctrl, thereby causing an adjustment to Vsns such that the direction of the voltage ramp turns downward. Again, as the voltage ramps downward, ramp counter 238 begins counting the time elapsed since the beginning of decrementing. This continues until the error voltage Verror falls to Vt_L, causing comparator 222 to assert the Inc signal. Once again, the count indicating the duration of the down ramp is stored, while ramp counter 238 changes the Count/DW output to DW_up.

The cycle described in the previous two paragraphs may continue for a total of N cycles, as input into ramp counter 238. After the Nth cycle is completed, averaging circuit 239 may calculate an average count value. In one embodiment, this average count value may be determined as follows:

$$Average Count = \frac{( {count}_{up} * D {W}_{up} + {count}_{d n} * D {W}_{d n} )}{{count}_{up} + {count}_{d n}} ,$$

where countᵤₚ is the average duration of the up ramp, count_{dn} is the average duration of the down ramp, DWᵤₚ is the fixed DW_up value, and DW_{dn} is the fixed DW_dn value. The resulting average count value is then provided to limit circuit as the digital equivalent used to set I_ctrl and thus to control Vsns and the input current limit.

### Timing Diagram:

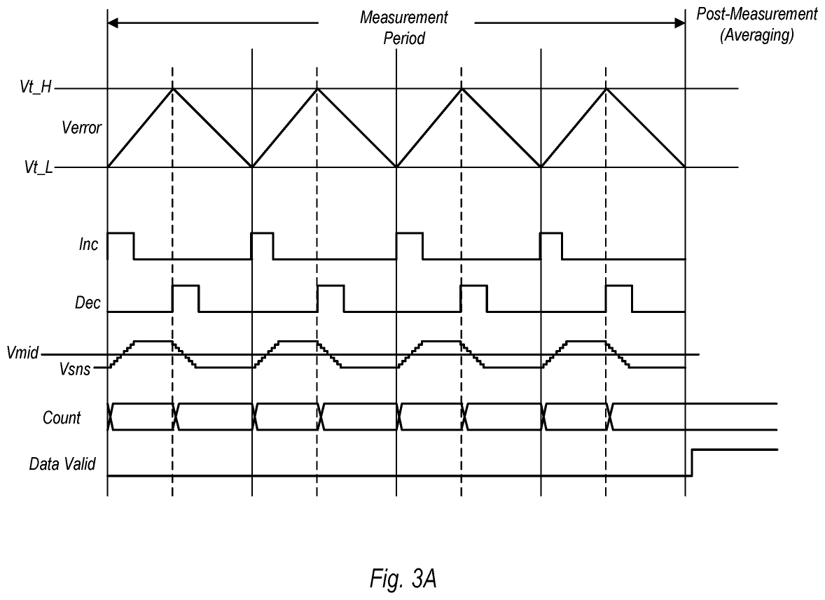

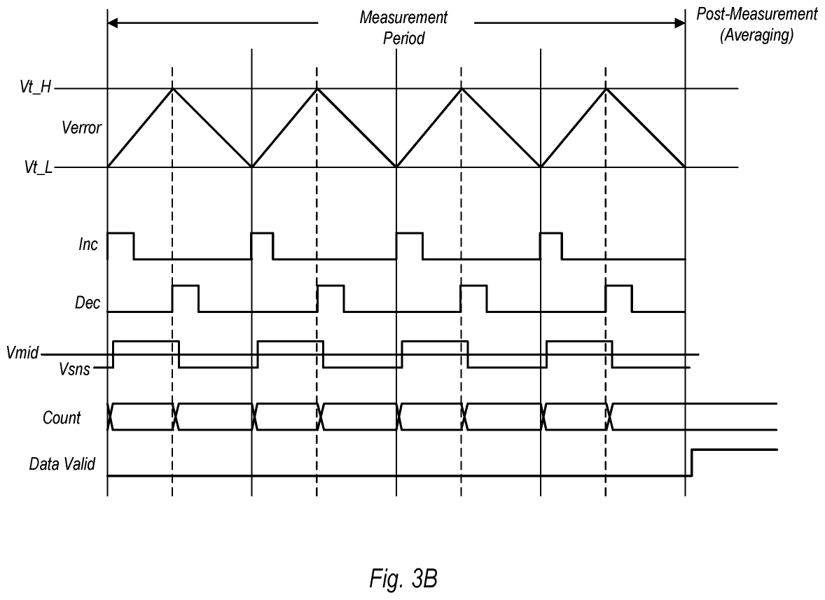

FIG. 3A is a timing diagram illustrating a calibration procedure carried out by one embodiment of a circuit for calibrating an input current. In the example of FIG. 3A, an embodiment of the circuitry described above according to FIG. 2A may carry out the calibration.

A calibration may be conducted over a measurement period. This measurement period may, in one embodiment, be determined by a number of clock cycles. During the calibration the error voltage rises and falls based on whether a count value is incremented or decremented. In the beginning of the illustrated example, the error voltage is at the lower threshold, Vt_L. This causes assertion of a signal received on the Inc (increment) input by the counter, which then begins incrementing the count. As a result of incrementing the count, the voltage Vsns is modified to increase. This continues until approximately the same time the Inc signal received by the counter is de-asserted. The voltage of the error signal continues rising until reaching the upper threshold, Vt_H. In responds to the voltage of the error signal reaching the upper threshold, the Dec signal is received by the counter, which then begins decrementing. Correspondingly, the voltage Vsns begins falling with the decrementing count value. This process repeats several times until the measurement period is terminated.

Upon termination of the measurement period, a data valid signal may be asserted indicating that the stored count values are ready for averaging. Thereafter, the average count value is computed and provided to the limit register of the limit circuit. This average count value represents the calibrated current limit value, and is used to regulate the input current during charging operations.

Calibrations such at that shown here may be carried out at various times in different embodiments. In one embodiment, the calibration procedure is carried out at the beginning of life for the portable device in which it is implemented. In some embodiments, the calibration may also be carried out any time the device is connected to an external power source to charge the battery.

FIG. 3B is a timing diagram illustrating a calibration procedure carried out by one embodiment of a circuit for calibrating an input current. In the example of FIG. 3B, an embodiment of the circuitry described above according to FIG. 2B may carry out the calibration.

In the embodiment shown, the timing is similar to that of the example shown in FIG. 3A. However, as noted in the description of FIG. 3B, two fixed data words (and thus fixed limit current values) may be used during the calibration procedure. Accordingly, as shown in FIG. 3B, the voltage Vsns takes one of two values during the procedure. During the error voltage up-ramp, Vsns is set at a value greater than Vmid, in accordance with the data word DW_up. During the error voltage down ramp, Vsns is set at a value less than V_mid, in accordance with the data word DW_dn. During the up ramp and down ramp times, the amount of time elapsed from the beginning of the up/down ramp until the corresponding threshold voltage (Vt_H on up-ramp, Vt_L on down ramp) is tracked using the count value. At the end of the measurement period, an averaging circuit may calculate the average count value per the formula given above, which can then be used to set the limit current in limit current circuit 210.

### Example Portable Device:

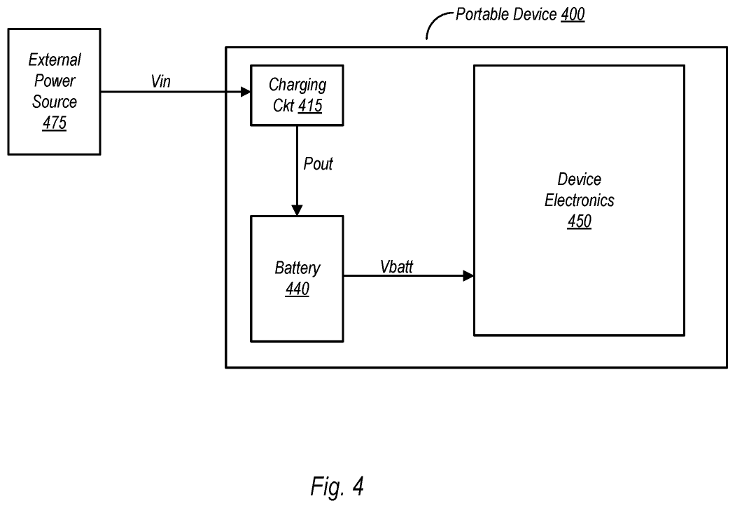

FIG. 4 is a block diagram of one embodiment of a portable device coupled to an embodiment of an external power source. In the embodiment shown, portable device 400 includes a charging circuit 415, a battery 440, and device electronics 450, which are powered by battery 440. An external power source 475 is shown as being coupled to charging circuit 415 to enable a battery charging operation to be carried out.

Charging circuit 415 may correspond to one of the embodiments discussed above, and more generally, to any suitable charging circuit. Although not explicitly shown here, portable device 400 may include the other circuits discussed above with reference to FIGS. 1 and 2, namely the input circuit, the calibration circuit, and the limit circuit.

In this particular embodiment, portable device is coupled to an external power source 475, which provides an input voltage, Vin. It is noted that this connection may be either a wired connection (e.g., via a USB port) or a wireless charging connection for embodiments of a device that are configured as such.

Charging circuit 415 in the embodiment shown is configured to provide output power, Pout, based on an input current I_in, to battery 440, during charging operations. The input current may be limited based on a current limit value calibrated as discussed above, and may determine the charging current provided to the battery. Limiting the input current may prevent damage to the battery and/or to circuits (such as those in an adapter) configured to act as the external power source.

### Methods of Operation:

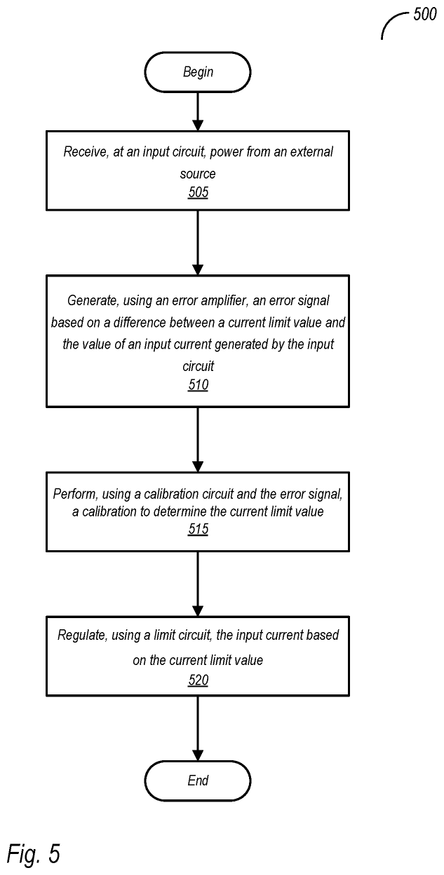

FIG. 5 is a flow diagram of one embodiment of a method for carrying out a calibration and regulation of an input current. Method 500 in the illustrated embodiment may be carried out by various ones of the hardware embodiments discussed above. Hardware embodiments capable of carrying out Method 500, but not otherwise disclosed herein, are also considered to fall within the scope of this disclosure.

Method 500 includes receiving, at an input circuit, power from an external source (block 505). The method further includes generating, using an error amplifier, an error signal based on a difference between a current limit value and the value of an input current generated by the input circuit (block 510) and performing, using a calibration circuit and the error signal, a calibration to determine the current limit value (block 515). The method also includes regulating, using a limit circuit, the input current based on the current limit value (block 520).

In various embodiments, the method includes providing, via first pass device coupled to an input pin, a first voltage to a first input of the error amplifier and generating, using a limit circuit and a second pass device coupled to the input pin, a second voltage. The method further includes providing the second voltage to a second input of the error amplifier and generating the error signal, using the amplifier, based on the first and second voltages. In some embodiments, generating the second voltage includes a current source generating a current based on the current limit value.

Some embodiments of the method include generating a first signal, using a first comparator, in response to the error signal reaching a first value and incrementing, using a counter, a count value in response to generating the first signal. Such embodiments may also include generating a second signal, using a second comparator, in response to the error signal reaching a second value decrementing the counter in response to generating the second signal. The calibration, including the counting (both incrementing and decrementing), may occur in accordance with a cycle of a clock signal. Accordingly, such embodiments may also include terminating the calibration after a specified number of clock cycles. After terminating the calibration, the method includes determining an average count value based on count values generated during the calibration. The method also includes using the average count value to set the current limit value. During the calibration, the method includes causing adjustments to the input current value by changing the count value.

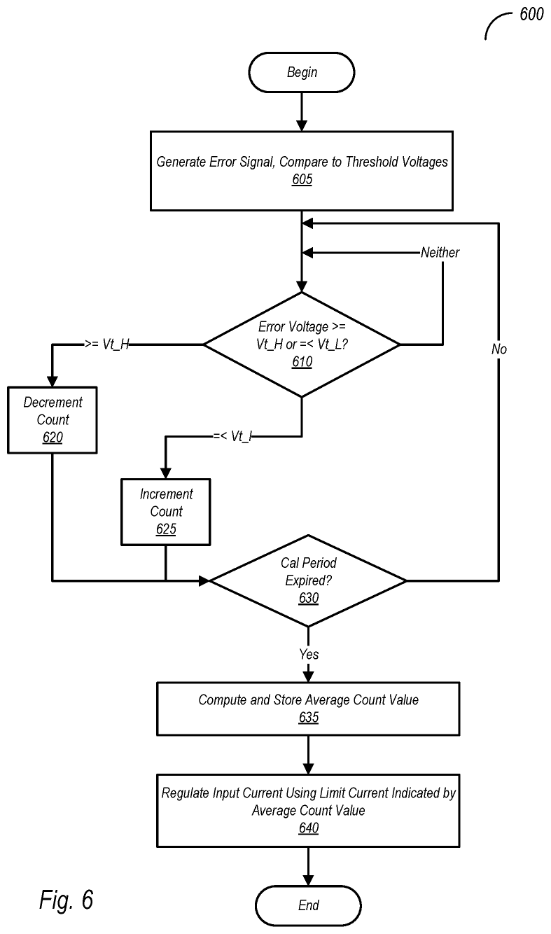

FIG. 6 is a flow diagram of another embodiment of a method for carrying out a calibration and regulation of an input current. Method 600 may be carried out by various embodiments of the hardware discussed above. Hardware embodiments not explicitly discussed herein, but otherwise capable of carrying out Method 600, are also considered to fall within the scope of this disclosure.

Method 600 includes generating an error signal and comparing a voltage of the error signal to threshold voltages (block 605). The error signal corresponds to a difference between first and second voltages generated based on an input current and a current limit value, respectively. The error signal may be compared to an upper voltage threshold (Vt_H) and a lower voltage threshold (Vt_L). If the error signal voltage is great than or equal to Vt_H (block 610, >=Vt_H), a comparator asserts a signal to cause a correspondingly coupled counter to decrement a count value (block 620). If the error signal voltage is less than or equal to Vt_L (block 610, =<Vt_L), another comparator asserts a signal to cause the counter to increment. Neither comparator asserts a signal when the voltage of the error signal is between these two limits.

If the calibration period has not expired (block 630, no), then the method continues with comparisons of the error signal voltage to the thresholds Vt_H and Vt_L. If the calibration period has expired (block 630, yes), then a computation of the average count value during the calibration period is carried out (block 635), and the value is stored. The average count value that is computed corresponds to a calibrated current limit value. Subsequently, during charging operations, the input current to the battery is regulated using the limit current indicated by the average count value (block 640).

### Example Device:

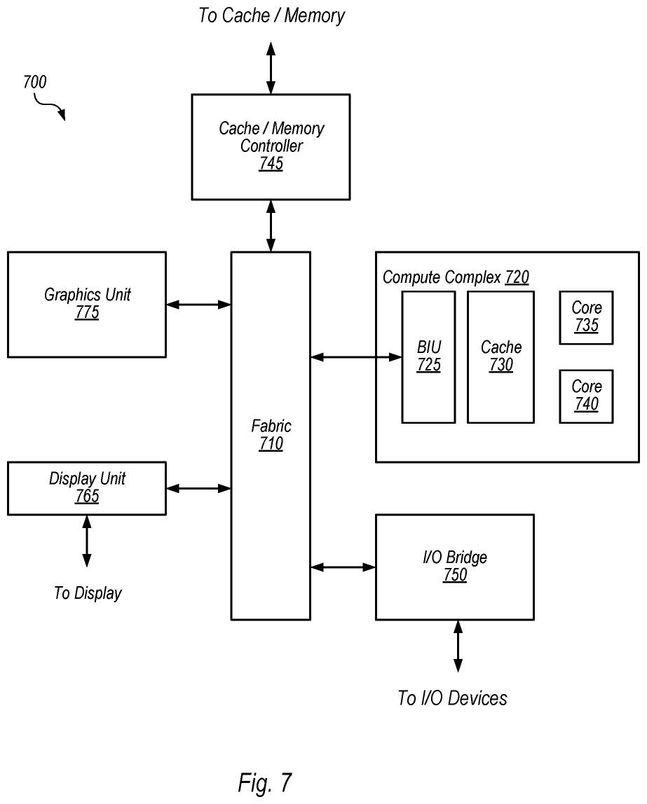

Referring now to FIG. 7, a block diagram illustrating an example embodiment of a device 700 is shown. In some embodiments, elements of device 700 may be included within a system on a chip. In some embodiments, device 700 may be included in a mobile device, which may be battery-powered. Therefore, power consumption by device 700 may be an important design consideration. In the illustrated embodiment, device 700 includes fabric 710, compute complex 720 input/output (I/O) bridge 750, cache/memory controller 745, graphics unit 775, and display unit 765. In some embodiments, device 700 may include other components (not shown) in addition to or in place of the illustrated components, such as video processor encoders and decoders, image processing or recognition elements, computer vision elements, etc.

Fabric 710 may include various interconnects, buses, MUX's, controllers, etc., and may be configured to facilitate communication between various elements of device 700. In some embodiments, portions of fabric 710 may be configured to implement various different communication protocols. In other embodiments, fabric 710 may implement a single communication protocol and elements coupled to fabric 710 may convert from the single communication protocol to other communication protocols internally.

In the illustrated embodiment, compute complex 720 includes bus interface unit (BIU) 725, cache 730, and cores 735 and 740. In various embodiments, compute complex 720 may include various numbers of processors, processor cores and caches. For example, compute complex 720 may include 1, 2, or 4 processor cores, or any other suitable number. In one embodiment, cache 730 is a set associative L2 cache. In some embodiments, cores 735 and 740 may include internal instruction and data caches. In some embodiments, a coherency unit (not shown) in fabric 710, cache 730, or elsewhere in device 700 may be configured to maintain coherency between various caches of device 700. BIU 725 may be configured to manage communication between compute complex 720 and other elements of device 700. Processor cores such as cores 735 and 740 may be configured to execute instructions of a particular instruction set architecture (ISA) which may include operating system instructions and user application instructions. These instructions may be stored in computer readable medium such as a memory coupled to memory controller 745 discussed below.

As used herein, the term “coupled to” may indicate one or more connections between elements, and a coupling may include intervening elements. For example, in FIG. 7, graphics unit 775 may be described as “coupled to” a memory through fabric 710 and cache/memory controller 745. In contrast, in the illustrated embodiment of FIG. 7, graphics unit 775 is “directly coupled” to fabric 710 because there are no intervening elements.

Cache/memory controller 745 may be configured to manage transfer of data between fabric 710 and one or more caches and memories. For example, cache/memory controller 745 may be coupled to an L3 cache, which may in turn be coupled to a system memory. In other embodiments, cache/memory controller 745 may be directly coupled to a memory. In some embodiments, cache/memory controller 745 may include one or more internal caches. Memory coupled to controller 745 may be any type of volatile memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR4, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an integrated circuit in a chip-on-chip configuration, a package-on-package configuration, or a multi-chip module configuration. Memory coupled to controller 745 may be any type of non-volatile memory such as NAND flash memory, NOR flash memory, nano RAM (NRAM), magneto-resistive RAM (MRAM), phase change RAM (PRAM), Racetrack memory, Memristor memory, etc. As noted above, this memory may store program instructions executable by compute complex 720 to cause the computing device to perform functionality described herein.

Graphics unit 775 may include one or more processors, e.g., one or more graphics processing units (GPUs). Graphics unit 775 may receive graphics-oriented instructions, such as OPENGL®, Metal®, or DIRECT3D® instructions, for example. Graphics unit 775 may execute specialized GPU instructions or perform other operations based on the received graphics-oriented instructions. Graphics unit 775 may generally be configured to process large blocks of data in parallel and may build images in a frame buffer for output to a display, which may be included in the device or may be a separate device. Graphics unit 775 may include transform, lighting, triangle, and rendering engines in one or more graphics processing pipelines. Graphics unit 775 may output pixel information for display images. Graphics unit 775, in various embodiments, may include programmable shader circuitry which may include highly parallel execution cores configured to execute graphics programs, which may include pixel tasks, vertex tasks, and compute tasks (which may or may not be graphics-related).

Display unit 765 may be configured to read data from a frame buffer and provide a stream of pixel values for display. Display unit 765 may be configured as a display pipeline in some embodiments. Additionally, display unit 765 may be configured to blend multiple frames to produce an output frame. Further, display unit 765 may include one or more interfaces (e.g., MIPI® or embedded display port (eDP)) for coupling to a user display (e.g., a touchscreen or an external display).

I/O bridge 750 may include various elements configured to implement: universal serial bus (USB) communications, security, audio, and low-power always-on functionality, for example. I/O bridge 750 may also include interfaces such as pulse-width modulation (PWM), general-purpose input/output (GPIO), serial peripheral interface (SPI), and inter-integrated circuit (I2C), for example. Various types of peripherals and devices may be coupled to device 700 via I/O bridge 750.

In some embodiments, device 700 includes network interface circuitry (not explicitly shown), which may be connected to fabric 710 or I/O bridge 750. The network interface circuitry may be configured to communicate via various networks, which may be wired, wireless, or both. For example, the network interface circuitry may be configured to communicate via a wired local area network, a wireless local area network (e.g., via Wi-Fi™), or a wide area network (e.g., the Internet or a virtual private network). In some embodiments, the network interface circuitry is configured to communicate via one or more cellular networks that use one or more radio access technologies. In some embodiments, the network interface circuitry is configured to communicate using device-to-device communications (e.g., Bluetooth® or Wi-Fi™ Direct), etc. In various embodiments, the network interface circuitry may provide device 700 with connectivity to various types of other devices and networks.

In various embodiments, device 700 may be implemented in a portable system such as smartphone, tablet computer, laptop computer, and so on, that include a rechargeable battery. Accordingly, such embodiments of a portable system may include various embodiments of the circuitry discussed above with reference to FIGS. 1-2 and/or circuitry configured to operate in accordance with FIGS. 3, 5, and 6.

### Example Applications

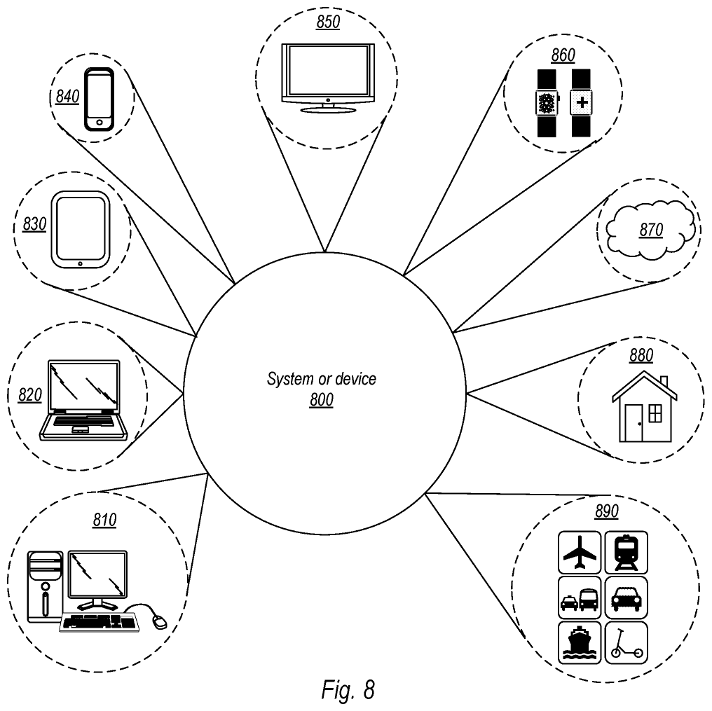

Turning now to FIG. 8, various types of systems that may include any of the circuits, devices, or system discussed above. System or device 800, which may incorporate or otherwise utilize one or more of the techniques described herein, may be utilized in a wide range of areas. For example, system or device 800 may be utilized as part of the hardware of systems such as a desktop computer 810, laptop computer 820, tablet computer 830, cellular or mobile phone 840, or television 850 (or set-top box coupled to a television).

Similarly, disclosed elements may be utilized in a wearable device 860, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 800 may also be used in various other contexts. For example, system or device 800 may be utilized in the context of a server computer system, such as a dedicated server or on shared hardware that implements a cloud-based service 870. Still further, system or device 800 may be implemented in a wide range of specialized everyday devices, including devices 880 commonly found in the home such as refrigerators, thermostats, security cameras, etc. The interconnection of such devices is often referred to as the “Internet of Things” (IoT). Elements may also be implemented in various modes of transportation. For example, system or device 800 could be employed in the control systems, guidance systems, entertainment systems, etc. of various types of vehicles 890.

In various embodiments, a system or device 800 as shown here may include a rechargeable battery. In such embodiments, the system or device 800 may also include charging circuitry and the corresponding calibration circuitry used to calibrate the input current for regulation during normal operation.

The applications illustrated in FIG. 8 are merely exemplary and are not intended to limit the potential future applications of disclosed systems or devices. Other example applications include, without limitation: portable gaming devices, music players, data storage devices, unmanned aerial vehicles, etc.

### Example Computer Readable Medium:

The present disclosure has described various example circuits in detail above. It is intended that the present disclosure cover not only embodiments that include such circuitry, but also a computer-readable storage medium that includes design information that specifies such circuitry. This includes various embodiments of the circuitry discussed above, including the charging and calibration circuitry of, e.g., FIGS. 1 and 2. Accordingly, the present disclosure is intended to support claims that cover not only an apparatus that includes the disclosed circuitry, but also a storage medium that specifies the circuitry in a format that programs a computing system to generate a simulation model of the hardware circuit, programs a fabrication system configured to produce hardware (e.g., an integrated circuit) that includes the disclosed circuitry, etc. Claims to such a storage medium are intended to cover, for example, an entity that produces a circuit design, but does not itself perform complete operations such as: design simulation, design synthesis, circuit fabrication, etc.

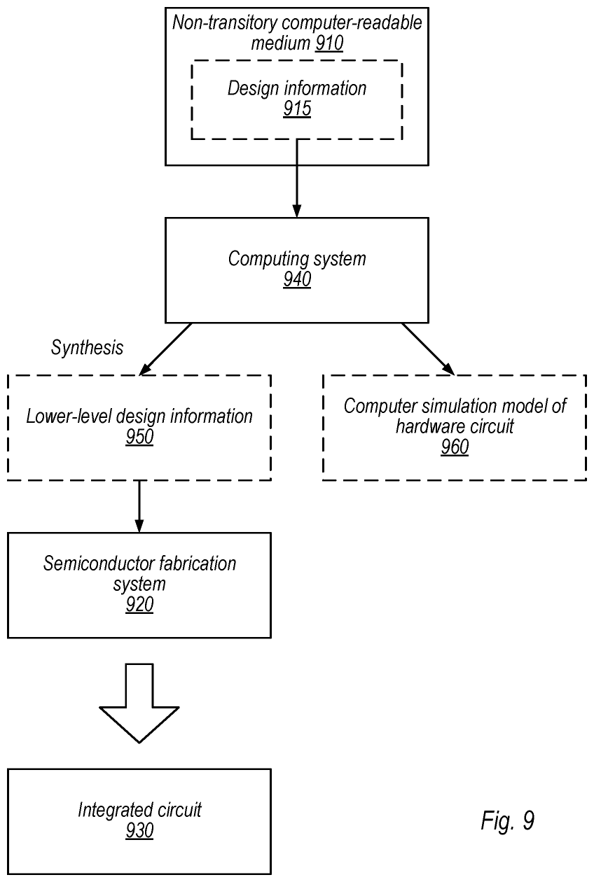

FIG. 9 is a block diagram illustrating an example non-transitory computer-readable storage medium that stores circuit design information, according to some embodiments. In the illustrated embodiment, computing system 940 is configured to process the design information. This may include executing instructions included in the design information, interpreting instructions included in the design information, compiling, transforming, or otherwise updating the design information, etc. Therefore, the design information controls computing system 940 (e.g., by programming computing system 940) to perform various operations discussed below, in some embodiments.

In the illustrated example, computing system 940 processes the design information to generate both a computer simulation model of a hardware circuit 960 and lower-level design information 950. In other embodiments, computing system 940 may generate only one of these outputs, may generate other outputs based on the design information, or both. Regarding the computing simulation, computing system 940 may execute instructions of a hardware description language that includes register transfer level (RTL) code, behavioral code, structural code, or some combination thereof. The simulation model may perform the functionality specified by the design information, facilitate verification of the functional correctness of the hardware design, generate power consumption estimates, generate timing estimates, etc.

In the illustrated example, computing system 940 also processes the design information to generate lower-level design information 950 (e.g., gate-level design information, a netlist, etc.). This may include synthesis operations, as shown, such as constructing a multi-level network, optimizing the network using technology-independent techniques, technology dependent techniques, or both, and outputting a network of gates (with potential constraints based on available gates in a technology library, sizing, delay, power, etc.). Based on lower-level design information 950 (potentially among other inputs), semiconductor fabrication system 920 is configured to fabricate an integrated circuit 930 (which may correspond to functionality of the simulation model 960). Note that computing system 940 may generate different simulation models based on design information at various levels of description, including information 950, 915, and so on. The data representing design information 950 and model 960 may be stored on medium 910 or on one or more other media.

In some embodiments, the lower-level design information 950 controls (e.g., programs) the semiconductor fabrication system 920 to fabricate the integrated circuit 930. Thus, when processed by the fabrication system, the design information may program the fabrication system to fabricate a circuit that includes various circuitry disclosed herein.

Non-transitory computer-readable storage medium 910, may comprise any of various appropriate types of memory devices or storage devices. Non-transitory computer-readable storage medium 910 may be an installation medium, e.g., a CD-ROM, floppy disks, or tape device; a computer system memory or random access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. Non-transitory computer-readable storage medium 910 may include other types of non-transitory memory as well or combinations thereof.

Accordingly, non-transitory computer-readable storage medium 910 may include two or more memory media; such media may reside in different locations—for example, in different computer systems that are connected over a network.

Design information 915 may be specified using any of various appropriate computer languages, including hardware description languages such as, without limitation: VHDL, Verilog, SystemC, SystemVerilog, RHDL, M, MyHDL, etc. The format of various design information may be recognized by one or more applications executed by computing system 940, semiconductor fabrication system 920, or both. In some embodiments, design information may also include one or more cell libraries that specify the synthesis, layout, or both of integrated circuit 930. In some embodiments, the design information is specified in whole or in part in the form of a netlist that specifies cell library elements and their connectivity. Design information discussed herein, taken alone, may or may not include sufficient information for fabrication of a corresponding integrated circuit. For example, design information may specify the circuit elements to be fabricated but not their physical layout. In this case, design information may be combined with layout information to actually fabricate the specified circuitry.

Integrated circuit 930 may, in various embodiments, include one or more custom macrocells, such as memories, analog or mixed-signal circuits, and the like. In such cases, design information may include information related to included macrocells. Such information may include, without limitation, schematics capture database, mask design data, behavioral models, and device or transistor level netlists. Mask design data may be formatted according to graphic data system (GDSII), or any other suitable format.

Semiconductor fabrication system 920 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 920 may also be configured to perform various testing of fabricated circuits for correct operation.

In various embodiments, integrated circuit 930 and model 960 are configured to operate according to a circuit design specified by design information 915, which may include performing any of the functionality described herein. For example, integrated circuit 930 may include any of various elements shown in FIGS. 1-5B. Further, integrated circuit 930 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components. Similarly, stating “instructions of a hardware description programming language” that are “executable” to program a computing system to generate a computer simulation model” does not imply that the instructions must be executed in order for the element to be met, but rather specifies characteristics of the instructions. Additional features relating to the model (or the circuit represented by the model) may similarly relate to characteristics of the instructions, in this context. Therefore, an entity that sells a computer-readable medium with instructions that satisfy recited characteristics may provide an infringing product, even if another entity actually executes the instructions on the medium.

Note that a given design, at least in the digital logic context, may be implemented using a multitude of different gate arrangements, circuit technologies, etc. As one example, different designs may select or connect gates based on design tradeoffs (e.g., to focus on power consumption, performance, circuit area, etc.). Further, different manufacturers may have proprietary libraries, gate designs, physical gate implementations, etc. Different entities may also use different tools to process design information at various layers (e.g., from behavioral specifications to physical layout of gates).

Once a digital logic design is specified, however, those skilled in the art need not perform substantial experimentation or research to determine those implementations. Rather, those of skill in the art understand procedures to reliably and predictably produce one or more circuit implementations that provide the function described by the design information. The different circuit implementations may affect the performance, area, power consumption, etc. of a given design (potentially with tradeoffs between different design goals), but the logical function does not vary among the different circuit implementations of the same circuit design.

In some embodiments, the instructions included in the design information instructions provide RTL information (or other higher-level design information) and are executable by the computing system to synthesize a gate-level netlist that represents the hardware circuit based on the RTL information as an input. Similarly, the instructions may provide behavioral information and be executable by the computing system to synthesize a netlist or other lower-level design information. The lower-level design information may program fabrication system 920 to fabricate integrated circuit 930.

It is noted that while the circuits discussed above have been implemented using NMOS and PMOS transistors, the disclosure is not intended to limit embodiments falling within its scope to these types of devices. Thus, in addition to various MOSFET types discussed above, the present disclosure also contemplates embodiments that use non-planar devices such as FinFETs, GAAFETs (Gate All Around FETs), among other types. Embodiments implemented using Bipolar devices are also possible and contemplated. The disclosure further contemplates that technologies that are speculative as of this writing may be used to implement devices in various embodiments of the circuits discussed herein. These technologies include (but are not limited to) graphene transistors, carbon nanotube transistors, gallium arsenide transistors, and so on. The use of memristors in certain circuit structures is also contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent claims that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some tasks even if the structure is not currently being operated. Thus, an entity described or recited as being “configured to” perform some tasks refers to something physical, such as a device, circuit, a system having a processor unit and a memory storing program instructions executable to implement the task, etc. This phrase is not used herein to refer to something intangible.

In some cases, various units/circuits/components may be described herein as performing a set of tasks or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements may be defined by the functions or operations that they are configured to implement. The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used to transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g. passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

Numerous variations and modifications will become apparent to those skilled in the art once the above disclosure is fully appreciated. It is intended that the following claims be interpreted to embrace all such variations and modifications.

What is claimed is:

1. An apparatus comprising:
an input circuit configured to receive power from an external source;
an error amplifier configured to generate an error signal based on a difference between a current limit value and a value of an input current generated by the input circuit;
a calibration circuit configured to perform, using the error signal, a calibration to determine the current limit value; and
a limit circuit configured to regulate the input current received by the input circuit based on the current limit value.

2. The apparatus of claim 1, wherein the input circuit includes a first pass device coupled to an input pin, wherein the first pass device is further coupled to a first input of the error amplifier, wherein the input circuit further includes a sense circuit having a second pass device coupled to the input pin, wherein the second pass device is further coupled to a second input of the error amplifier.

3. The apparatus of claim 2, wherein the error amplifier is configured to generate the error signal based on a first voltage received on the first input, the first voltage corresponding to the input current, and a second voltage on the second input, the second voltage is generated by the second pass device and the limit circuit.

4. The apparatus of claim 3, wherein the limit circuit comprises a current source coupled to the second pass device and the second input of the error amplifier, wherein the current source is configured to modify the second voltage based on the current limit value.

5. The apparatus of claim 1, wherein the calibration circuit includes:
a first comparator configured to generate a first signal in response to the error signal reaching a first value; and
a second comparator configured to generate a second signal in response to the error signal reaching a second value.

6. The apparatus of claim 5, wherein the calibration circuit further includes a counter, wherein the counter is configured to increment in response to assertion of the first signal and further configured to decrement in response to assertion of the second signal.

7. The apparatus of claim 6, wherein the counter is configured to, upon completion of the calibration, generate an average count value corresponding to a calibrated current limit value.

8. The apparatus of claim 6, wherein, during the calibration, the counter is configured to, using a current count value, cause adjustments to the current limit value.

9. The apparatus of claim 6, wherein the limit circuit comprises a register configured to store a calibrated current limit value received from the calibration circuit, wherein, during normal operation, the limit circuit is configured to regulate the input current based on the calibrated current limit value.

10. The apparatus of claim 1, further comprising a charging circuit coupled to the input circuit and the error amplifier, wherein the charging circuit is configured to cause charging of a battery using an input current regulated by the limit circuit.

11. A method comprising:
receiving, at an input circuit, power from an external source;
generating, using an error amplifier, an error signal based on a difference between a current limit value and a value of an input current generated by the input circuit;
performing, using a calibration circuit and the error signal, a calibration to determine the current limit value; and
regulating, using a limit circuit, the input current based on the current limit value.

12. The method of claim 11, further comprising:
providing, via first pass device coupled to an input pin, a first voltage to a first input of the error amplifier;
generating, using a limit circuit and a second pass device coupled to the input pin, a second voltage;
providing the second voltage to a second input of the error amplifier; and
generating the error signal, using the error amplifier, based on the first and second voltages.

13. The method of claim 12, wherein generating the second voltage further comprises a current source generating a current based on the current limit value.

14. The method of claim 11, wherein performing the calibration comprises:
generating a first signal, using a first comparator, in response to the error signal reaching a first value;
incrementing, using a counter, a count value in response to generating the first signal;
generating a second signal, using a second comparator, in response to the error signal reaching a second value; and
decrementing the counter in response to generating the second signal.

15. The method of claim 14, further comprising:
terminating the calibration after a specified number of clock cycles;
determining an average count value based on count values generated during the calibration; and
using the average count value to set the current limit value.

16. The method of claim 14, further comprising, during the calibration, causing adjustments to the value of the input current by changing the count value.

17. A system comprising:
a charging circuit configured to charge a rechargeable battery;
a control circuit configured to control an input current generated by the charging circuit, wherein the control circuit includes:
an input circuit configured to convey power from an external source to the charging circuit;
an error amplifier configured to generate an error signal based on a difference between a first voltage indicative of the input current and a second voltage based on a current limit value;
a calibration circuit configured to perform, using the error signal, a calibration to determine the current limit value; and
a limit circuit configured to regulate the input current received by the input circuit based on the current limit value.

18. The system of claim 17, wherein the calibration circuit includes:
a first comparator configured to generate a first signal in response to the error signal reaching a first value;
a second comparator configured to generate a second signal in response to the error signal reaching a second value; and
a counter, wherein the counter is configured to increment in response to assertion of the first signal and further configured to decrement in response to assertion of the second signal;
wherein the counter is further configured to, upon completion of the calibration, generate an average count value corresponding to a calibrated current limit value.

19. The system of claim 17, wherein the limit circuit comprises a register configured to store a calibrated current limit value received from the calibration circuit, wherein, during normal operation, the limit circuit is configured to regulate the input current based on the calibrated current limit value.

20. The system of claim 17, wherein the input circuit includes:
a first pass device coupled to an input pin configured to convey a first voltage to a first input of the error amplifier and further configured to convey the first voltage to the charging circuit, wherein the first voltage is based on a voltage provided by an external source coupled to the input pin;
a second pass device coupled between the input pin and a second input of the error amplifier; and
wherein the limit circuit includes:
a current source coupled to the second pass device and the second input of the error amplifier; and
a current control circuit configured to control an amount of current generated by the current source using the current limit value, wherein the current source is configured to modify a second voltage provided to the second input of the error amplifier.
